(19) United States
(12) Patent Application Publication
(10) Pub. No.: US 2007/0082418 A1
(43) Pub. Date: Apr. 12, 2007

(54) Method for manufacturing a light emitting device and light emitting device made therefrom

(75) Inventors: Dong-Sing Wuu, Taichung City (TW); Ray-Hua Horng, Taichung City (TW)

Correspondence Address: FOLEY AND LARDNER LLP;SUITE 500, 3000 K STREET NW, WASHINGTON, DC, 20007, US

(73) Assignee: National Chung-Hsing University

(21) Appl. No.: 11/246,229

(22) Filed: Oct. 11, 2005

(51) Int. Cl. H01L 21/00

(52) U.S. Cl. 438/22

(57) ABSTRACT

A method for manufacturing a light emitting device includes forming an epitaxial layer on a substrate, forming first and second electrodes that are electrically coupled to said epitaxial layer, forming a transparent layer on the epitaxial layer, forming particles of a mask material that are randomly scattered on a surface of the transparent layer, etching and texturing the surface of the transparent layer so as to form dents, that are scattered among the particles of the mask material, in the textured surface of the transparent layer, and removing the particles of the mask material from the textured surface of the transparent layer.

### BACKGROUND OF THE INVENTION

1. Field of the Invention

This invention relates to a method for manufacturing a light emitting device, more particularly to a method for manufacturing a light emitting device involving replacement of a traditional epitaxial window layer with a non-epitaxial transparent layer, and formation of dents in a textured surface of the transparent layer by using particles of a mask material.

2. Description of the Related Art

Due to dramatic progress in solid state light emitting devices, such as light emitting diodes (LEDs), they have become popular for use as light sources. In particular, the light emitting devices are widely and popularly used in applications of traffic lights, brake lights, cellular phones, and outdoor signs, due to their characteristics of high intensity of emitted light, high output power, and good reliability.

In the past, researches and developments in the field of light emitting diodes have been directed to enhancement of internal quantum efficiency and intensity of emitted light through improvement in the quality of the epitaxy layer of the light emitting diodes using molecular beam epitaxy (MBE) or metal-organic chemical vapor deposition (MOCVD) techniques.

However, the light emitting diodes that only have high internal quantum efficiency are not satisfactory, and are required to be further improved in the light extraction efficiency.

FIG. 1 illustrates atypical light emitting diode (LED) 1 of the conventional red or yellow light emitting diodes of AlGaInP or GaP series. The LED 1 shown in FIG. 1 includes a substrate 11, a light emitting unit 12, and an electrode unit 13.

The light emitting unit 12 is formed on the substrate 1 by epitaxial techniques, and includes an N-type cladding layer 121 formed on the substrate 11, an active layer 122 formed on the N-type cladding layer 121, a P-type cladding layer 123 formed on the active layer 122, and a window layer 124 formed on the P-type cladding layer 123.

The electrode unit 13 includes an N-type electrode 132 formed on and electrically connected to the N-type cladding layer 122, and a P-type electrode 131 formed on the window layer 124 and electrically connected to the P-type cladding layer 123 through the window layer 124.

In order to increase the intensity and uniformity of light emitted by the abovementioned LED 1, a plurality of dents 15 are randomly formed in a textured surface of the window layer 124 by etching techniques, so as to reduce total internal reflection of light and so as to enhance external quantum efficiency of the LED 1, when the light emitted by the active layer 122 passes through the window layer 124 to exit the LED 1.

Generally, the dents 15 are required to have a depth of at least 0.2 μm so as to achieve the required external quantum efficiency. The window layer 124 of the conventional red or yellow LEDs 1 of AlGaInP or GaP series has a thickness larger than 1 μm, even larger than 50 μm, and is suitable for forming dents 15 in the textured surface thereof through etching techniques, such as plasma etching or chemical etching. However, the etching techniques are not suitable for formation of dents in a textured surface of a window layer of UV or blue/green. LEDs, because the window layer of these LEDs has a relatively thin thickness, such as about 0.4 μm.

Therefore, there is still a need in the art to provide a method suitable for forming dents, which meet the depth requirement for enhancement of external quantum efficiency, in the textured surface of the window layer of the LEDs that has a thickness as thin as 0.4 μm or less.

### SUMMARY OF THE INVENTION

Therefore, the object of the present invention is to provide a method for manufacturing a light emitting device and a light emitting device made therefrom that can overcome the problems encountered by the abovementioned prior art.

According to one aspect of this invention, a method for manufacturing a light emitting device includes forming an epitaxial layer on a substrate, forming first and second electrodes that are electrically coupled to the epitaxial layer, forming a transparent layer on the epitaxial layer, forming particles of a mask material that are randomly scattered on a surface of the transparent layer, etching and texturing the surface of the transparent layer so as to form dents scattered among the particles of the mask material in the textured surface of the transparent layer, and removing the particles of the mask material from the textured surface of the transparent layer.

According to another aspect of this invention, a light emitting device includes a substrate, an epitaxial layer formed on the substrate, a transparent layer formed on the epitaxial layer, having a textured surface formed with a plurality of dents, and made from a conductive material selected from the group consisting of Ni/Au, ITO, IZO, Ni/ITO, Ni/IZO, Ni/TiN, Ti/TiN, Ti/IrO₂, and mixtures thereof, and first and second electrodes that are electrically coupled to the epitaxial layer.

According to yet another aspect of this invention, a light emitting device includes a substrate, an epitaxial layer formed on the substrate, a transparent layer formed on the epitaxial layer, having a textured surface formed with a plurality of dents, and made from a non-conductive material selected from the group consisting of SiO₂, Si₃N₄, TiO₂, Ta₂O₅, Al₂O₃, and mixtures thereof, and first and second electrodes that are electrically coupled to the epitaxial layer.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 is a schematic sectional view to illustrate a conventional semiconductor light emitting device;

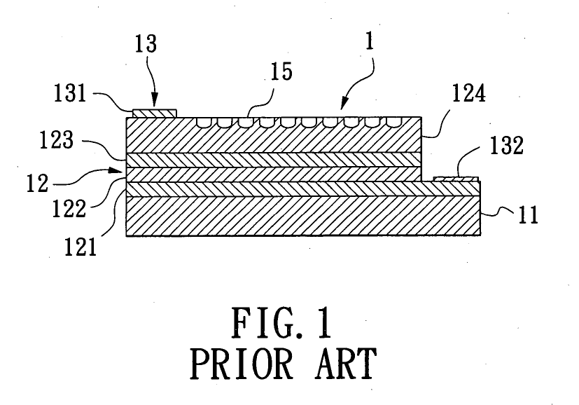

FIG. 2 is a flow chart to illustrate consecutive steps of the preferred embodiment of a method for manufacturing a light emitting device according to this invention;

FIG. 3 is a schematic sectional view to illustrate the first preferred embodiment of a light emitting device according to this invention;

FIG. 4 is a schematic view to illustrate the second preferred embodiment of a light emitting device according to this invention; and

FIG. 5 is a schematic view to illustrate a structural modification of the second preferred embodiment of the light emitting device of FIG. 4.

### DETAILED DESCRIPTION OF THE PREFERRED EMBODIMENTS

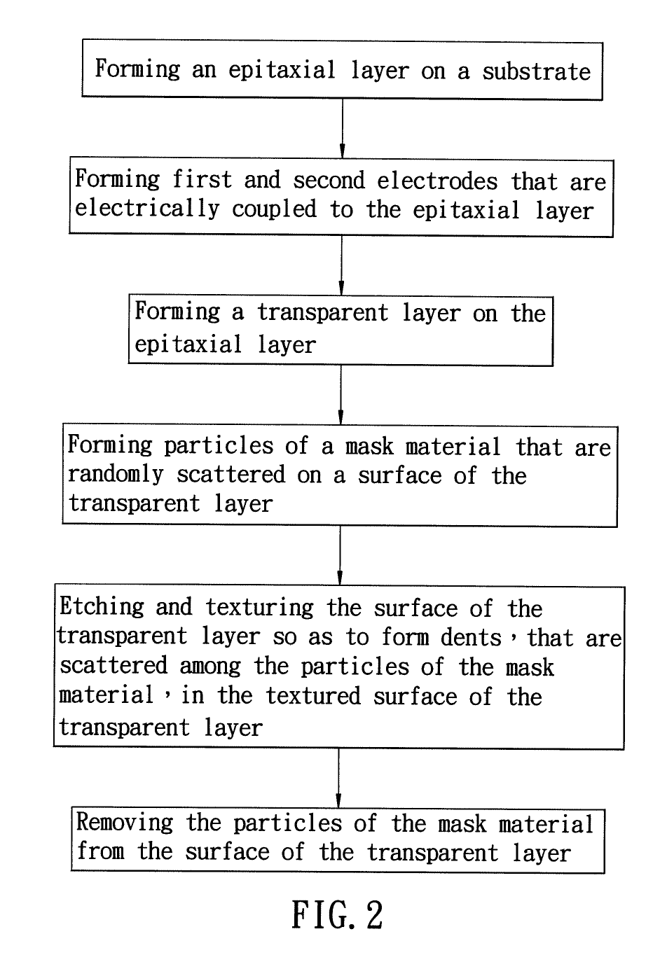

Referring to FIG. 2, the preferred embodiment of a method for manufacturing a light emitting device according to this invention includes the steps of: forming an epitaxial layer on a substrate, forming first and second electrodes that are electrically coupled to the epitaxial layer, forming a transparent layer on the epitaxial layer, forming particles of a mask material that are randomly scattered on a surface of the transparent layer, etching and texturing the surface of the transparent layer so as to form dents, that are scattered among the particles of the mask material, in the textured surface of the transparent layer, and removing the particles of the mask material from the textured surface of the transparent layer.

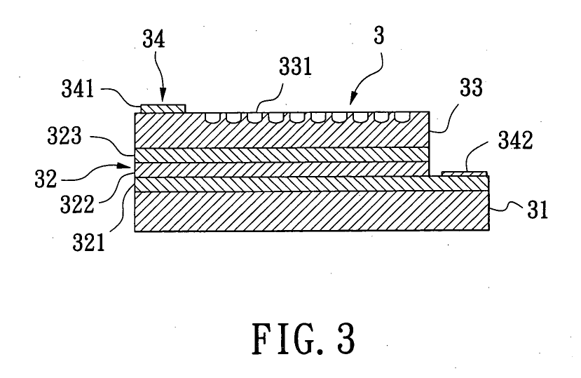

With further reference to FIG. 3, the first preferred embodiment of a light emitting device 3 according to this invention is illustrated. The light emitting device 3 can be used as UV or blue/green LEDs. Manufacture of the light emitting device 3 starts from forming an epitaxial layer 32 on a substrate 31. Preferably, the substrate 31 is made from a material selected from the group consisting of single crystal sapphire, GaN and SiC.

The epitaxial layer 32 includes an N-type cladding sub-layer 321 formed on the substrate 31, an active sub-layer 322 formed on the N-type cladding sub-layer 321, and a P-type cladding sub-layer 323 formed on the active sub-layer 322. Preferably, the active sub-layer 322 has a structure selected from one of heterostructure, multi-quantum wells, and mutli-quantum dots (MQDs) so as to emit light having good quantum effect through photoelectric effect.

A transparent layer 33 is then formed on the P-type cladding sub-layer 323 and is in ohmic contact with the P-type cladding sub-layer 323. The transparent layer 33 is made from a conductive material selected from the group consisting of Ni/Au, indium tin oxide (ITO), indium zinc oxide (IZO) , Ni/ITO, Ni/IZO, Ni/TiN, Ti/TiN, Ti/IrO₂, and mixtures thereof. In addition, the transparent layer 33 has a thickness that is larger than that of the P-type cladding sub-layer 323 and that has a value not equal to integral multiples of λ/4n, wherein λ represents wavelength of the light emitted by the active sub-layer 322 and n represents refractive index of the transparent layer 33. The thickness of the transparent layer 33 thus formed favors enhancement of external quantum efficiency of the light emitting device 3. Notely, the thickness of the transparent layer 33 is thicker than that of the P-type cladding sub-layer 323.

An electrode unit 34 including a first electrode 342 and a second electrode 341 is subsequently formed on the light emitting device 3. The first electrode 342 is formed on the N-type cladding sub-layer 321, and is in ohmic contact therewith. The second electrode 341 is formed on the transparent layer 33 so as to be electrically connected to the P-type cladding sub-layer 323 through the transparent layer 33, and is in ohmic contact therewith. When a proper current is applied to the second electrode 341 and flows through the epitaxial layer 32, the active sub-layer 322 will emit light due to photoelectric effect.

Next, a resist layer (not shown) is formed on the second electrode 341 so as to protect the second electrode 341 during the etching process. A plurality of particles of a mask material are formed by applying a film of a solution of the mask material on a surface of the transparent layer 33, followed by drying the film on the surface of the transparent layer 33. The resist layer is preferably made from a polymeric material. The mask material is preferably made from a transparent conductive polymeric material or a transparent compound. The transparent conductive polymeric material is selected from the group consisting of polystyrene, polypropylene, polyethylene, and mixtures thereof. The transparent compound is an oxide or nitride selected from the group consisting of Al₂O₃, SiO₂, Si₃N₄, BN, and mixtures thereof. Alternatively, the particles of the mask material are made from nanodiamonds. The particles formed on the transparent layer 33 have an average particle size smaller than the wavelength of the light emitted by the active sub-layer 322.

After formation of the resist on the second electrode 341 and the particles of the mask material on the transparent layer 33, the transparent layer 33 is etched and textured through plasma etching or chemical wet etching techniques, so as to form dents 331 that are scattered among the particles of the mask material in the textured surface of the transparent layer 33. The dents 331 have an average depth less than 0.2 μm.

Finally, the resist and the particles of the mask material are removed from the second electrode 341 and the textured surface of the transparent layer 33, respectively, so as to obtain the light emitting device 3 with the textured surface. Alternatively, since the particles of the mask material are transparent and conductive, the operation for removing the particles of the mask material can be omitted without causing adverse effect on external quantum efficiency of the light emitting device 3.

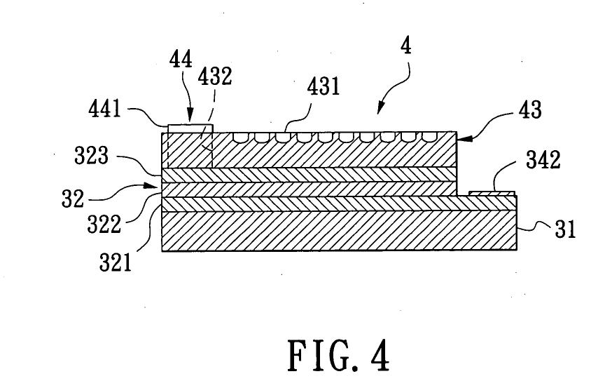

Referring to FIG. 4, the second preferred embodiment of a light emitting device 4 according to this invention is illustrated. The light emitting device 4 has a structure similar to that of the light emitting device 3 shown in FIG. 3, except for the material of the transparent layer 43 and the arrangement of the second electrode 441 in the electrode unit 44. In this embodiment, the transparent layer 43 is made from a transparent non-conductive material selected from the group consisting of SiO₂, Si₃N₄, TiO₂, Ta₂O₅, Al₂O₃, and mixtures thereof. Additionally, the transparent layer 43 is further formed with a through-hole 432 to expose a portion of the P-type cladding sub-layer 323. The second electrode 441 is formed in the through-hole 432 so as to be in contact with and electrically connected to the exposed portion of the P-type cladding sub-layer 323.

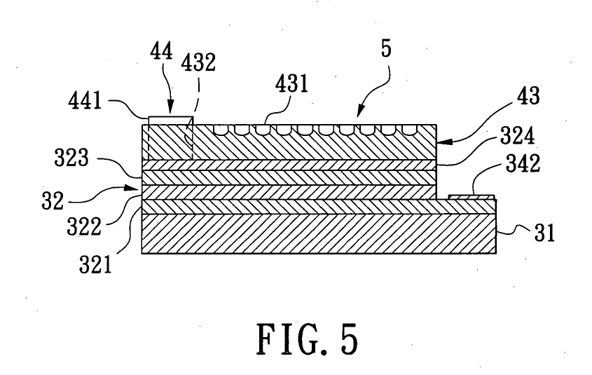

The light emitting device 5 shown in FIG. 5 is a structural modification of the second preferred embodiment of the light emitting device of FIG. 4. The light emitting device 5 of FIG. 5 has a structure similar to that of the light emitting device 4 of FIG. 4, except that the epitaxial layer 32 further includes a current-spreading layer 324 formed on the P-type cladding sub-layer 323 and that the transparent layer 43 is formed on the current-spreading layer 324. Formation of the current-spreading layer 324 will enhance uniformity of current flowing through the active sub-layer 322. The current-spreading layer 324 is made from a transparent conductive material selected from Ni/Au, ITO, IZO, Ni/ITO, Ni/IZO, Ni/TiN, Ti/TiN, Ti/IrO₂, and mixtures thereof.

According to the method of this invention, by replacing the traditional epitaxial window layer 124 with the transparent layer 33, 43 and by forming the particles of the mask material on the transparent layer 33, 43, the dents 331, 431 with a depth larger than 0.2 μm can be achieved in either of UV or blue/green light emitting devices by etching techniques.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A method for manufacturing a light emitting device, comprising:
forming an epitaxial layer on a substrate;
forming first and second electrodes that are electrically coupled to said epitaxial layer;
forming a transparent layer on the epitaxial layer;
forming particles of a mask material that are randomly scattered on a surface of the transparent layer;
etching and texturing the surface of the transparent layer so as to form dents, that are scattered among the particles of the mask material, in the textured surface of the transparent layer; and
removing the particles of the mask material from the textured surface of the transparent layer.

2. The method of claim 1, wherein the particles of the mask material are formed by applying a film of a solution of the mask material on the surface of the transparent layer, followed by drying the film on the surface of the transparent layer.

3. The method of claim 2, wherein the mask material is made from a polymeric material selected from the group consisting of polystyrene, polypropylene, polyethylene and mixtures thereof.

4. The method of claim 2, wherein the mask material is made from a compound selected from the group consisting of Al₂O₃, SiO₂, Si₃N₄, BN, and mixtures thereof.

5. The method of claim 1, wherein the particles of the mask material are made from nanodiamonds.

6. The method of claim 1, wherein the epitaxial layer includes an N-type cladding sub-layer formed on the substrate, an active sub-layer formed on the N-type cladding sub-layer, and a P-type cladding sub-layer formed on the active sub-layer, and wherein the first electrode is formed on the N-type cladding sub-layer.

7. The method of claim 6, wherein the transparent layer is made from a conductive material selected from the group consisting of Ni/Au, ITO, IZO, Ni/ITO, Ni/IZO, Ni/TiN, Ti/TiN, Ti/IrO₂, and mixtures thereof.

8. The method of claim 7, wherein the second electrode is formed on the transparent layer so as to be electrically connected to the P-type cladding sub-layer through the transparent layer.

9. The method of claim 6, wherein the transparent layer is made from a non-conductive material selected from the group consisting of SiO₂, Si₃N₄, TiO₂, Ta₂O₅, Al₂O₃, and mixtures thereof.

10. The method of claim 9, wherein the transparent layer is formed with a through-hole to expose a portion of the P-type cladding sub-layer, and wherein the second electrode is formed in the through-hole so as to be electrically connected to the exposed portion of the P-type cladding sub-layer.

11. A light emitting device, comprising:
a substrate;
an epitaxial layer formed on said substrate;
a transparent layer formed on said epitaxial layer, having a textured surface formed with a plurality of dents, and made from a conductive material selected from the group consisting of Ni/Au, ITO, IZO, Ni/ITO, Ni/IZO, Ni/TiN, Ti/TiN, Ti/IrO₂, and mixtures thereof; and
first and second electrodes that are electrically coupled to said epitaxial layer.

12. The light emitting device of claim 11, wherein said epitaxial layer includes an N-type cladding sub-layer, an active sub-layer formed on said N-type cladding sub-layer, a P-type cladding sub-layer formed on said active sub-layer in such a manner that said first electrode is formed on said N-type cladding sub-layer, that said transparent layer is formed on said P-type cladding sub-layer, and that said second electrode is formed on said transparent layer.

13. A light emitting device, comprising:
a substrate;
an epitaxial layer formed on said substrate;
a transparent layer formed on said epitaxial layer, having a textured surface formed with a plurality of dents, and made from a non-conductive material selected from the group consisting of SiO₂, Si₃N₄, TiO₂, Ta₂O₅, Al₂O₃, and mixtures thereof; and
first and second electrodes that are electrically coupled to said epitaxial layer.

14. The light emitting device of claim 13, wherein said transparent layer is further formed with a through-hole to expose a portion of said epitaxial layer, said second electrode being formed in said through-hole to contact said epitaxial layer.

15. The light emitting device of claim 14, wherein said epitaxial layer includes an N-type cladding sub-layer formed on said substrate, an active sub-layer formed on said N-type cladding sub-layer, a P-type cladding sub-layer formed on said active sub-layer in such a manner that said first electrode is formed on said N-type cladding sub-layer and that said second electrode contacts a portion of said P-type cladding sub-layer, which is exposed from said though-hole.

16. The light emitting device of claim 14, wherein said epitaxial layer includes an N-type cladding sub-layer formed on said substrate, an active sub-layer formed on said N-type cladding sub-layer, a P-type cladding sub-layer formed on said active sub-layer, and a current-spreading layer formed on said P-type cladding sub-layer, and wherein said first and second electrodes are formed on said N-type cladding sub-layer and electrically coupled to said current-spreading layer, respectively.
